(19) United States
(12) Patent Application Publication
(10) Pub. No.: US 2007/0293027 A1
(43) Pub. Date: Dec. 20, 2007

(54) DOPANT DIFFUSION METHOD AND METHOD OF MANUFACTURING SEMICONDUCTOR DEVICE

(75) Inventors: Takuya Konno, Kanagawa-ken (JP); Ichiro Mizushima, Kanagawa-ken (JP); Takashi Suzuki, Kanagawa-ken (JP); Nobuaki Makino, Kanagawa-ken (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 11/687,315

(22) Filed: Mar. 16, 2007

(30) Foreign Application Priority Data
Mar. 28, 2006 (JP) 2006-088682

(51) Int. Cl. H01L 21/223

(52) U.S. Cl. 438/565; 257/E21.141

(57) ABSTRACT

A dopant diffusion method includes: diffusing a dopant element into a semiconductor through an oxide film. The dopant element is contained in a compound gas having a gas partial pressure of not less than 0.1 torr and not more than 800 torr. A temperature of the semiconductor is set less than 750° C. and not more than 950° C. A method of manufacturing a semiconductor device including a semiconductor with a dopant element diffused therein, the method includes: diffusing a dopant element into the semiconductor through an oxide film. The dopant element is contained in a compound gas having a gas partial pressure of not less than 0.1 torr and not more than 800 torr, and a temperature of the semiconductor is set less than 750° C. and not more than 950° C.

### CROSS-REFERENCE TO RELATED APPLICATIONS

This application is based upon and claims the benefit of priority from the prior Japanese Patent Application No. 2006-088682, filed on Mar. 28, 2006; the entire contents of which are incorporated herein by reference.

### BACKGROUND OF THE INVENTION

1. Field of the Invention

This invention relates to a dopant diffusion method and a method of manufacturing a semiconductor device, and more particularly to a dopant diffusion method and a method of manufacturing a semiconductor device where a gas containing an n-type or p-type dopant element is used.

2. Background Art

Ion implantation and gas-phase diffusion are used for doping a semiconductor with impurities.

Ion implantation is a technique where accelerated dopant ions are implanted to form a diffusion layer having a desired peak dopant concentration. However, this technique depends on the implantation direction. In a location where dopant ions are difficult to implant such as the sidewall of a deep trench in a DRAM (Dynamic Random Access Memory), a highly-doped shallow diffusion layer is not readily obtained. Furthermore, because implanted dopant ions are accelerated, damages may occur.

Gas-phase diffusion is a technique where heat treatment is conducted in a gas atmosphere containing a dopant element, thereby diffusing the dopant element into a semiconductor. Thus a diffusion layer can be formed in a portion exposed to the dopant gas. Hence a diffusion layer can be formed without difficulty even in the sidewall of a deep trench. However, in this technique, it is difficult to control the peak dopant concentration and the diffusion depth. In particular, it is not easy to stably obtain, for example, high peak dopant concentrations of 3×10¹⁹ cm⁻³ or more and shallow diffusion layers.

In this context, in a method disclosed in JP 11-204450A, a dopant layer is allowed to adsorb on a semiconductor substrate by gas-phase diffusion, and then oxygen or the like is supplied to form a layer for preventing out-diffusion and volatilization of dopants. By thermal diffusion, the concentration is increased.

### SUMMARY OF THE INVENTION

According to an aspect of the invention, there is provided a dopant diffusion method including: a diffusing a dopant element into a semiconductor through an oxide film, the dopant element being contained in a compound gas having a gas partial pressure of not less than 0.1 torr and not more than 800 torr, and a temperature of the semiconductor being set not less than 750° C. and not more than 950° C.

According to another aspect of the invention, there is provided a method of manufacturing a semiconductor device including a semiconductor with a dopant element diffused therein, the method comprising: diffusing a dopant element into the semiconductor through an oxide film, the dopant element being contained in a compound gas having a gas partial pressure of not less than 0.1 torr and not more than 800 torr, and a temperature of the semiconductor being set less than 750° C. and not more than 950° C.

### BRIEF DESCRIPTION OF THE DRAWINGS

FIG. 1 is a flow chart showing a dopant diffusion method related to a first example of the invention.

FIG. 2 is a graph showing a dopant profile.

FIG. 3 is a flow chart showing a dopant diffusion method according to the first example of the invention.

FIG. 4 is a graph showing a dopant profile for the film thickness of the oxide film in the first example.

FIG. 5 is a graph showing the relationship between the thickness of the oxide film and the sheet resistance in a semiconductor substrate.

FIG. 6 is a graph showing a dopant profile for the gas partial pressure of a compound gas in doping phosphorus.

FIG. 7 is a flow chart showing a dopant diffusion method according to a second example of the invention.

FIG. 8 is a graph showing a dopant profile for the processing time in doping phosphorus in the second example.

FIG. 9 is a graph showing a dopant profile in doping arsenic.

### DETAILED DESCRIPTION OF THE INVENTION

An embodiment of the invention will now be described with reference to the drawings. In the description of this embodiment, a monocrystalline silicon substrate is used as an example of the substrate or semiconductor substrate (reference to this point is omitted in the following).

As an example of the invention, a dopant diffusion method of forming a diffusion layer having a high peak dopant concentration is now described.

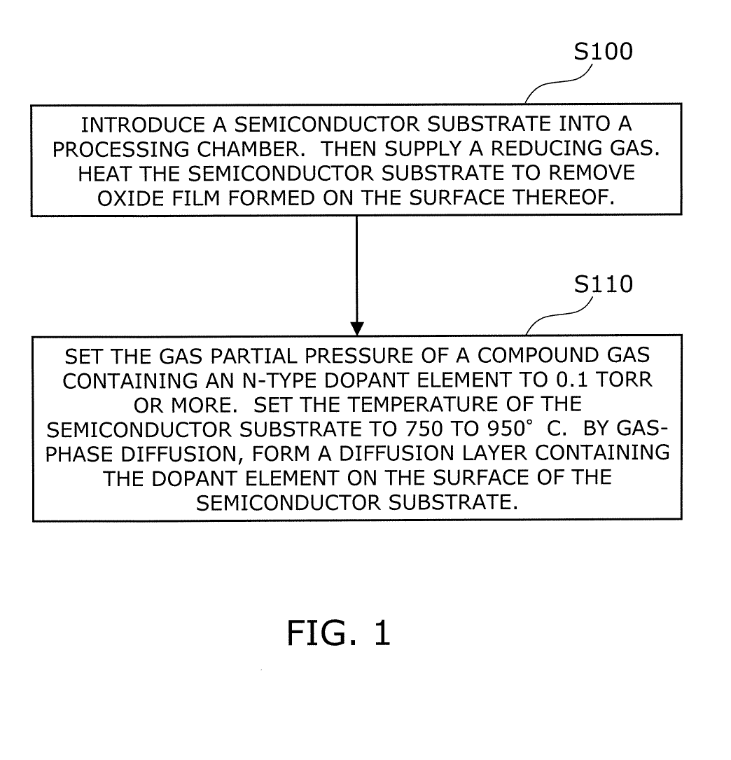

FIG. 1 is a flow chart showing a dopant diffusion method related to a first example of the invention.

First, a semiconductor substrate is introduced into a processing chamber. Then the processing chamber is evacuated, a reducing gas is supplied thereto, and the semiconductor substrate is heated, thereby removing the oxide film formed on the surface of the semiconductor substrate (step S100).

Thus the surface of the semiconductor substrate is cleaned. The oxide film is removed under the condition that, for example, the reducing gas is hydrogen gas having a pressure of about 1 torr and the semiconductor substrate is kept at a temperature of 950° C. for 1 hour.

Then the supply of the reducing gas is stopped, and a gas containing a dopant element is passed. The gas containing a dopant element may illustratively be phosphine (PH₃) gas having a gas partial pressure higher than 1 torr. The temperature of the semiconductor substrate is set to 750 to 950° C. Thus, by gas-phase diffusion, a diffusion layer containing a dopant element can be formed in the vicinity of the surface of the semiconductor substrate (step S110). Nitrogen (N₂) gas can illustratively be used as a carrier gas of the compound gas. Here, the total pressure of the compound gas can illustratively be set to 380 torr.

In this step, phosphorus and phosphorus compounds produced by the decomposition of the gas are attached to the cleaned surface of the semiconductor substrate. Then phosphorus diffuses into the semiconductor substrate. Thus an n-type diffusion layer having a high peak dopant concentration of 3×10¹⁹ cm⁻³ or more is formed in the vicinity of the surface of the semiconductor substrate.

In the manufacturing method of this technique, after the oxide film formed on the surface of the semiconductor substrate is removed, the reducing gas can be replaced by the compound gas to form a diffusion layer containing a dopant element.

Continuous formation using the same processing chamber is achieved.

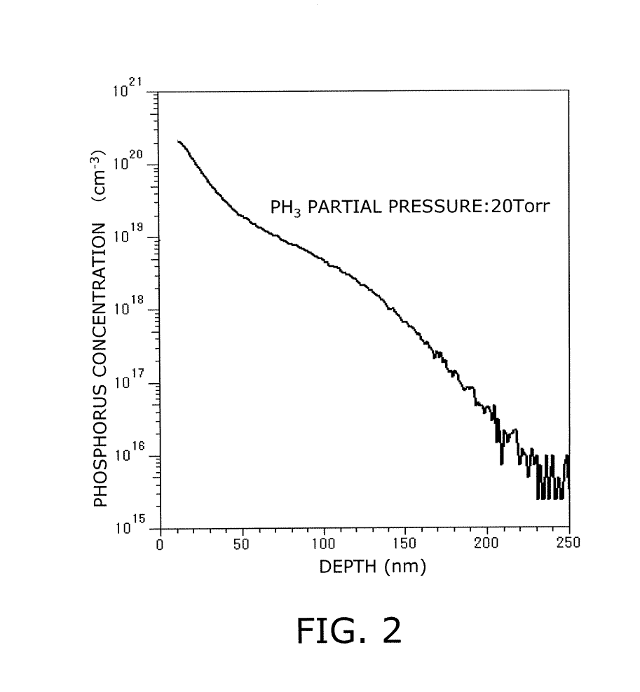

FIG. 2 is a graph showing a dopant profile obtained by this reference example.

The horizontal axis represents the diffusion depth (in nanometers), and the vertical axis represents the phosphorus concentration (in cm⁻³). The phosphorus concentration was measured by SIMS (Secondary Ion Mass Spectrometry). Gas-phase diffusion was conducted under the condition that the partial pressure of PH₃ gas is 20 torr, the temperature of the semiconductor substrate is 850° C., and the processing time is 10 minutes.

It is seen that, according to this reference example, a peak dopant concentration of e.g. 2×10²⁰ cm⁻³ is obtained at a diffusion depth of about 10 nanometers from the surface. Thus an n-type diffusion layer having a high peak dopant concentration can be formed by controlling the PH₃ gas partial pressure and the temperature of the semiconductor substrate.

However, when the compound gas has a gas partial pressure of less than 0.1 torr, a peak dopant concentration of 3×10¹⁹ cm⁻³ or more cannot be obtained. Furthermore, when the temperature of the semiconductor substrate is 750° C. or less, a peak dopant concentration of 2×10²⁰ cm⁻³ cannot be obtained as well because of insufficient diffusion. On the other hand, when the temperature of the semiconductor substrate is 1200° C. or more, the solubility of phosphorus in the semiconductor substrate decreases, and it is observed that the peak diffusion concentration tends to decrease.

According to this reference example, a shallow diffusion layer having a high peak dopant concentration can be formed even in the sidewall of a deep trench in a DRAM (Dynamic Random Access Memory), for example, independent of the configuration of the semiconductor substrate. Furthermore, also in the process of forming a source and a drain of a CMOS transistor or other semiconductor device, a shallow dopant diffusion layer having a high peak concentration can be easily formed.

Next, as an example of the invention, a method of controlling the dopant profile is described.

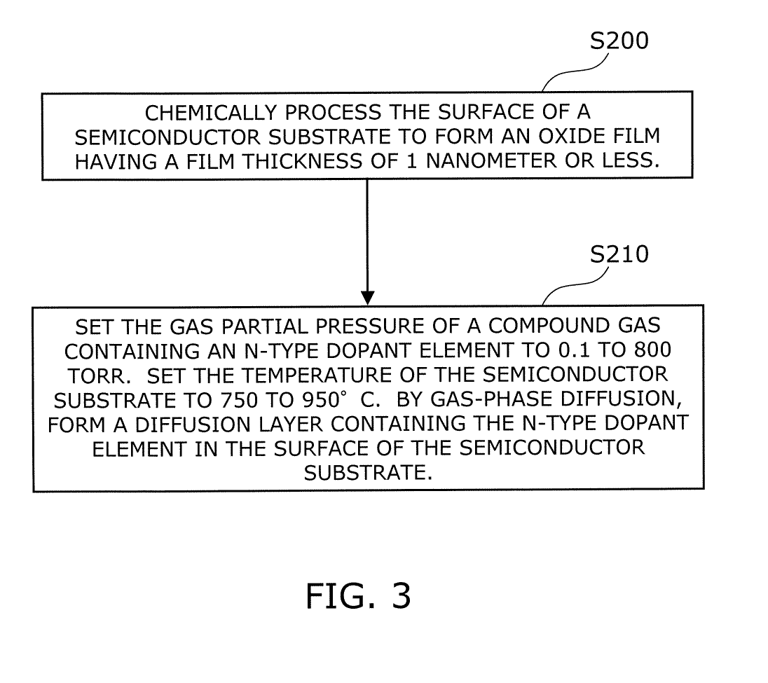

FIG. 3 is a flow chart showing a dopant diffusion method according to the example of the invention.

In this example, the surface of a semiconductor substrate is processed with a chemical solution to form an oxide film having a film thickness of 1 nanometer or less (step S200). Here, as the chemical solution, it is possible to use, for example, a mixed solution of hydrochloric acid (HCl), hydrogen peroxide (H₂O₂), and pure water (H₂O) with a composition ratio of 1:1:5 (volume ratio), or a mixed solution of ammonia (NH₄OH), hydrogen peroxide (H₂O₂), and pure water (H₂O) with a composition ratio of 1:1:5 (volume ratio).

Next, the supply of the reducing gas is stopped, and then a compound gas containing an n-type dopant element such as PH₃ gas is supplied to the processing chamber.

Then, as described later, the gas partial pressure of the compound gas is set to 0.1 to 800 torr, and the temperature of the semiconductor substrate is set to 750 to 950° C. Thus, by gas-phase diffusion, a diffusion layer containing a dopant element is formed in the surface of the semiconductor substrate (step S210). Here, when the temperature is lower than 750° C., sufficient doping is difficult. When the temperature exceeds 950° C., the oxide film formed on the semiconductor substrate may be reduced away.

Phosphorus and compounds thereof produced by the decomposition of PH₃ gas are attached to the oxide film formed on the surface of the semiconductor substrate. Then the attached phosphorus diffuses into the semiconductor substrate, and thereby an n-type diffusion layer having a controlled dopant profile is formed in the vicinity of the surface of the semiconductor substrate.

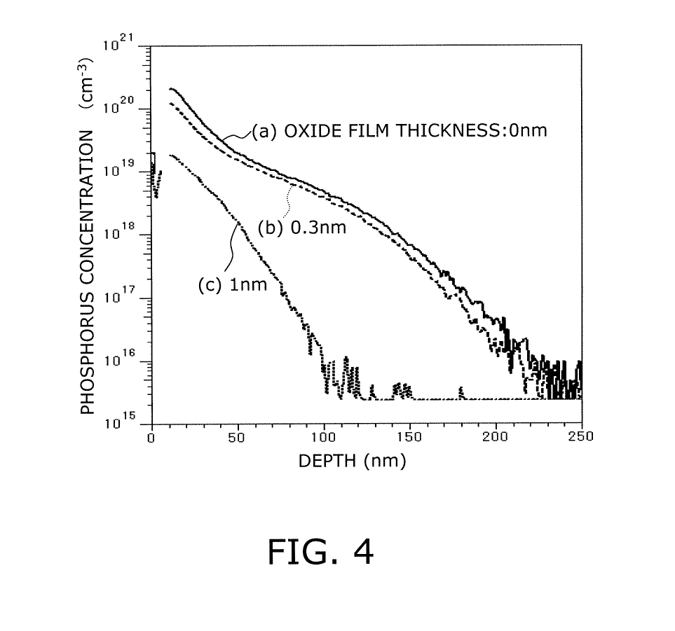

FIG. 4 is a graph showing a dopant profile for the film thickness of the oxide film formed on the semiconductor substrate according to this example.

The horizontal axis represents the diffusion depth (in nanometers), and the vertical axis represents the phosphorus concentration (in cm⁻³). The film thickness of the oxide film is 0 nanometer for curve (a), 0.3 nanometer for curve (b), and 1.0 nanometer for curve (c). The phosphorus concentration was measured by SIMS. Gas-phase diffusion was conducted under the condition that the partial pressure of PH₃ gas is 20 torr, the temperature of the semiconductor substrate is 850° C., and the processing time is 10 minutes.

It is seen from FIG. 4 that the diffusion depth and the peak dopant concentration of the phosphorus element decrease with the increase of the film thickness of the oxide film. Thus the diffusion depth and the peak dopant concentration of the phosphorus element can be controlled by controlling the thickness of the oxide film.

Here, for example, when a mixed solution of sulfuric acid (H₂SO₄) and hydrogen peroxide (H₂O₂) with a composition ratio of 4:1 (volume ratio) is used, the film thickness of the oxide film is larger than 1 nanometer. Then the dopant concentration significantly decreases, and the desired peak dopant concentration is not achieved.

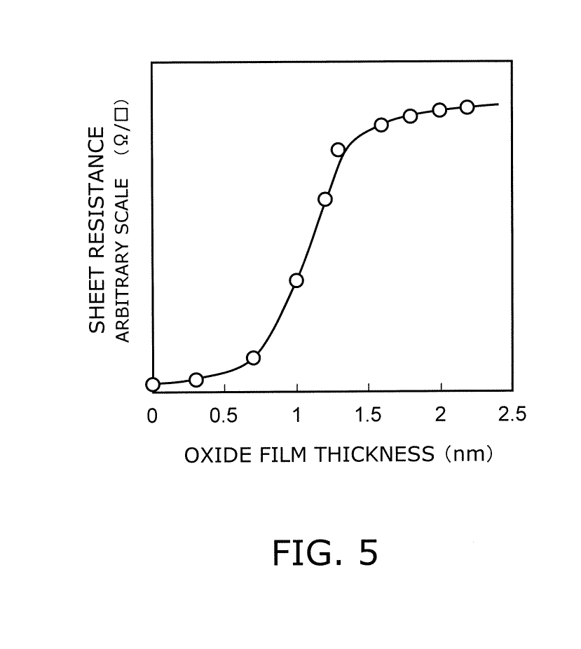

FIG. 5 is a graph showing the relationship between the thickness of the oxide film and the sheet resistance in a semiconductor substrate.

The horizontal axis represents the thickness of the oxide film (in nanometers), and the vertical axis represents the sheet resistance (Ω/□). The relationship between the dopant concentration and the resistance can translate into the relationship of the film thickness of the oxide film to the sheet resistance, and consequently to the diffusion depth and the peak dopant concentration of the phosphorus element, for example.

It is seen from FIG. 5 that, as the oxide film thickens, the sheet resistance of the semiconductor substrate increases. When the thickness of the oxide film exceeds 1 nanometer, the sheet resistance turns to a high level.

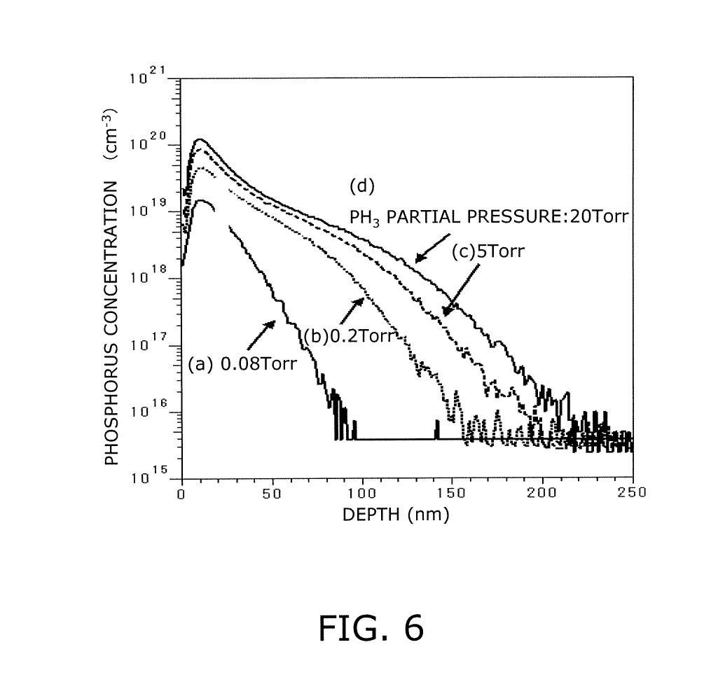

FIG. 6 is a graph showing a dopant profile for the gas partial pressure of a compound gas in doping phosphorus in this example.

The horizontal axis represents the diffusion depth (in nanometers), and the vertical axis represents the logarithm of the phosphorus concentration (in cm⁻³). The gas partial pressure of the compound gas is 0.08 torr for curve (a), 0.2 torr for curve (b), 5 torr for curve (c), and 20 torr for curve (d). The phosphorus concentration was measured by SIMS. Gas-phase diffusion was conducted under the condition that the film thickness of the oxide film is 0.3 nanometer, the temperature of the semiconductor substrate is 850° C., and the processing time is 10 minutes.

It is seen from FIG. 6 that the diffusion depth and the peak dopant concentration decrease with the decrease of the gas partial pressure of the compound gas. Thus it is seen from FIGS. 4, 5, and 6 that the diffusion depth and the peak dopant concentration of the phosphorus element can be accurately controlled by controlling the thickness of the oxide film and the gas partial pressure of the compound gas.

Here, as seen from FIG. 6, when the gas partial pressure of the compound gas is less than 0.1 torr, the desired peak dopant concentration is not achieved. On the other hand, from the viewpoint of safety in manufacturing semiconductor devices, it is preferable to prevent the gas partial pressure of the compound gas from exceeding 800 torr, which is about 5 percent higher than the atmosphere. Furthermore, when the temperature is 950° C. or more, the oxide film formed is reduced away, and hence it is difficult to control the dopant profile.

As described above, according to this example, the film thickness of the oxide film is controlled by chemical processing, and the gas partial pressure of the compound gas containing phosphorus or other dopant is controlled to conduct gas-phase diffusion. Thus the dopant profile can be accurately controlled.

### SECOND EXAMPLE

Next, a dopant diffusion method is described as a second example of the invention where the dopant diffusion methods described above in the first example are combined to achieve a high peak dopant concentration with a controlled dopant profile.

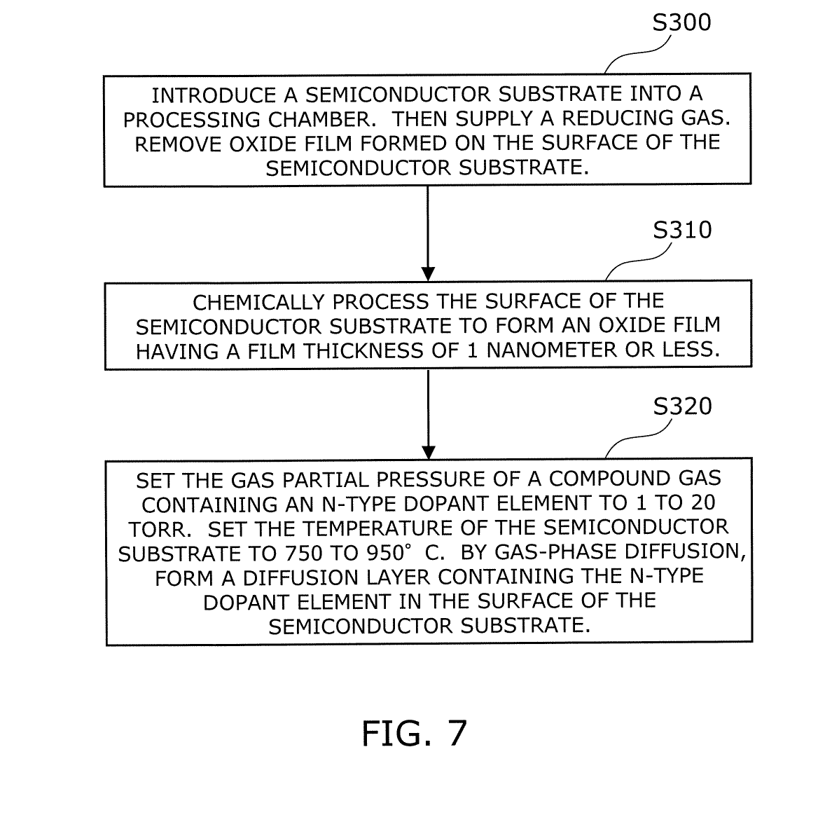

FIG. 7 is a flow chart showing a dopant diffusion method according to a second example of the invention.

First, like the first example, a semiconductor substrate is introduced into a processing chamber. Then a reducing gas is supplied thereto so that the processing chamber has a pressure of about 1 torr, thereby removing the oxide film formed on the surface of the semiconductor substrate (step S300). Thus the surface of the semiconductor substrate can be cleaned. The reducing treatment is conducted under the condition that, for example, like the first example, the reducing gas is hydrogen having a pressure of 1 torr and the semiconductor substrate is kept at a temperature of 950° C. for 1 hour.

Then the semiconductor substrate is taken out of the processing chamber, and the surface of the semiconductor substrate is processed with a chemical solution to form an oxide film having a film thickness of 1 nanometer or less (step S310). As described above with reference to the first example, it is possible to use, as the chemical solution, a mixed solution of hydrochloric acid (HCl), hydrogen peroxide (H₂O₂), and pure water (H₂O) with a composition ratio of 1:1:5 (volume ratio), for example. The film thickness of the oxide film is set to 1 nanometer or less, and illustratively to 0.3 nanometer. By this chemical processing, an oxide film having a film thickness of 1 nanometer or less can be obtained.

Next, the semiconductor substrate is introduced into the processing chamber.

The partial pressure of a compound gas containing an n-type dopant element such as PH₃ gas is set to 1 to 20 torr, and the temperature of the semiconductor substrate is set to 750 to 950° C. Thus, by gas-phase reaction, a diffusion layer containing the n-type dopant element is formed in the surface of the semiconductor substrate (step S320).

As described above with reference to the first example, phosphorus and compounds thereof produced by the decomposition of PH₃ gas are attached to the oxide film formed on the surface of the semiconductor substrate. Then phosphorus diffuses into the semiconductor substrate. Thus an n-type diffusion layer having a high peak dopant concentration and a shallow diffusion profile is formed in the vicinity of the surface of the semiconductor substrate.

In the following, the diffusion depth of the diffusion layer formed with various diffusion times in this example is described.

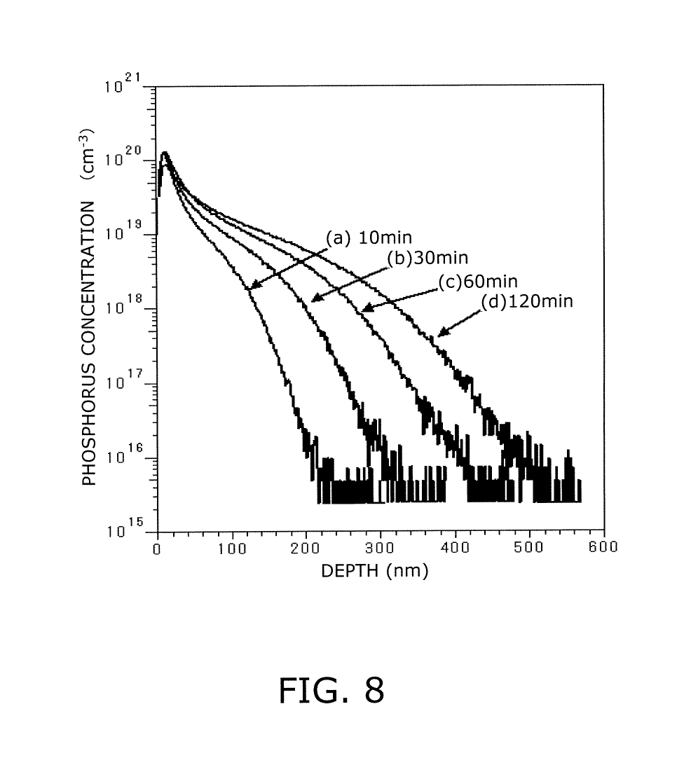

FIG. 8 is a graph showing a dopant profile for the processing time in diffusing phosphorus in this example.

The horizontal axis represents the diffusion depth (in nanometers), and the vertical axis represents the phosphorus concentration (in cm⁻³). The processing time is 10 minutes for curve (a), 30 minutes for curve (b), 60 minutes for curve (c), and 120 minutes for curve (d). The phosphorus concentration was measured by SIMS. It is seen from FIG. 8 that a peak dopant concentration of about 1×10²⁰ cm⁻³ is obtained independent of the processing time. In the profile shown, the diffusion depth increases as the processing time increases. That is, the diffusion depth is correlated with the diffusion time. Thus the diffusion profile of the diffusion layer can be controlled by adapting the thickness of the oxide film and the processing time to applications and purposes.

The embodiment of the invention has been described with reference to examples. However, the invention is not limited to these examples. For example, the invention is widely applicable to semiconductor devices including DRAM, SRAM (Static Random Access Memory), and flash memory; discrete devices such as a transistor, IGBT (Insulated Gate Bipolar Transistor), and diode; and integrated circuit devices such as a microprocessor and logic circuit.

In the examples described above, PH₃ gas is used as the compound gas. However, the invention is not limited thereto, but a similar effect can be achieved by using arsine (AsH₃) gas, for example.

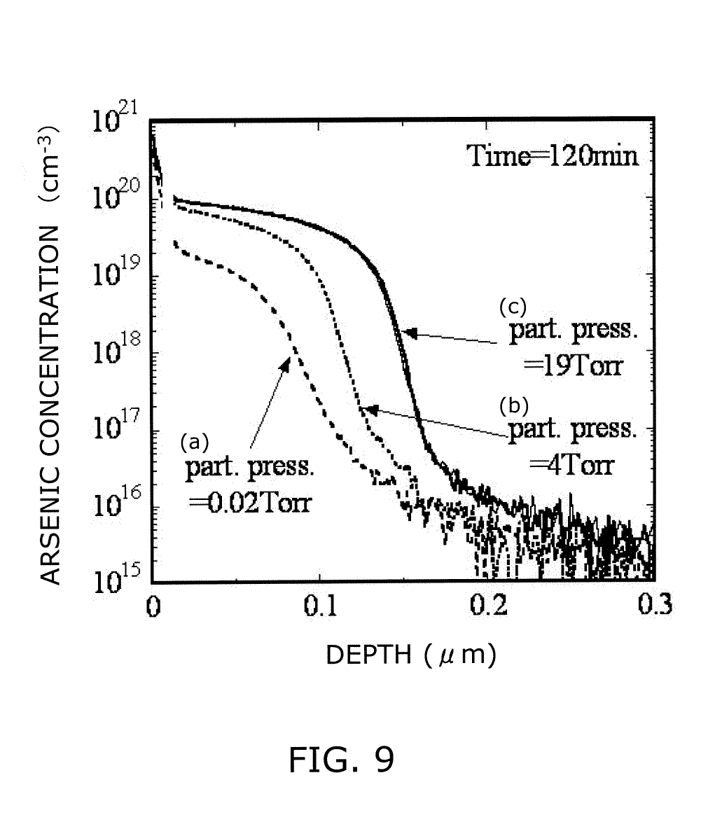

FIG. 9 is a graph showing a dopant profile in doping arsenic using arsine. The horizontal axis represents the diffusion depth (in nanometers), and the vertical axis represents the arsenic concentration (in cm⁻³).

By a method similar to the first example, a diffusion layer was formed with As being diffused in the vicinity of the surface of a semiconductor substrate. In the gas-phase diffusion process using arsine, the processing time was set to 120 minutes, and the temperature of the semiconductor substrate was set to 950° C. The gas partial pressure of arsine is 19 torr for curve (a), 4 torr for curve (b), and 0.02 torr for curve (c). The arsenic concentration was measured by SIMS.

Like the first example described above, as the gas partial pressure of arsine increases, the peak dopant concentration increases, and the diffusion depth increases. A peak concentration of arsenic of 3×10¹⁹ cm⁻³ or more was achieved by setting the arsine partial pressure to 0.1 torr.

The invention can also be applied to a compound gas containing arsenic to form a shallow n-type diffusion layer having a high peak dopant concentration by increasing the partial pressure of the compound gas.

However, as shown in FIG. 9, the dopant profile for arsenic exhibits a different tendency from those for phosphorus shown in FIGS. 2, 4, and 7. More specifically, the profile for phosphorus exhibits a tendency where the phosphorus concentration linearly decreases with the increase of the diffusion depth. In contrast, in the case of arsenic, when the diffusion depth from the surface is about 0.1 to 0.15 micrometer, for example, the peak dopant concentration is generally constant. As the diffusion depth further increases, the arsenic concentration rapidly decreases. This difference of profiles presumably depends on the difference of diffusion rate between arsenic and phosphorus.

On the other hand, the invention can also be applied to a compound gas containing a p-type dopant such as boron (B) to similarly achieve a high concentration peak and a shallow diffusion profile.

In the examples, chemical processing is used to form an oxide film. However, the invention is not limited thereto. Furthermore, in the dopant diffusion method of the invention, various elements in the technique for removing an oxide film and the technique for forming an oxide film can be appropriately modified by those skilled in the art, and such modifications are also encompassed within the scope of the invention as long as they include the features of the invention.

As described above, in the present embodiment, a monocrystalline silicon substrate is illustratively used. Therefore, in the present embodiment, the controllability of the peak dopant concentration and the diffusion profile can be enhanced, and a dopant diffusion layer having a high concentration peak can be formed at a shallow position in the monocrystalline silicon substrate.

As described above, in the present embodiment, a shallow diffusion layer having a high peak dopant concentration can be formed even in the sidewall of a deep trench in a DRAM (Dynamic Random Access Memory), for example, independent of the configuration of the semiconductor substrate.

Furthermore, also in the process of forming a source and a drain of a CMOS transistor or other semiconductor device, a shallow dopant diffusion layer having a high peak concentration can be easily formed.

1. A dopant diffusion method comprising:
diffusing a dopant element into a semiconductor through an oxide film, the dopant element being contained in a compound gas having a gas partial pressure of not less than 0.1 torr and not more than 800 torr, and a temperature of the semiconductor being set not less than 750° C. and not more than 950° C.

2. The dopant diffusion method according to claim 1, further comprising, before the diffusing, forming the oxide film on a surface of the semiconductor.

3. The dopant diffusion method according to claim 2, further comprising, before the forming the oxide film on the surface of the semiconductor, supplying a reducing gas to remove another oxide film formed on the surface of the semiconductor.

4. The dopant diffusion method according to claim 1, wherein the oxide film has a thickness of 1 nanometer or less.

5. The dopant diffusion method according to claim 2, wherein the oxide film is formed by exposing the semiconductor to a chemical solution.

6. The dopant diffusion method according to claim 5, wherein the chemical solution includes hydrogen peroxide.

7. The dopant diffusion method according to claim 1, wherein the dopant diffused into the semiconductor has a peak concentration of 3×10¹⁹ cm⁻³ or more.

8. The dopant diffusion method according to claim 1, wherein the dopant element is phosphorus or arsenic.

9. The dopant diffusion method according to claim 1, wherein the gas partial pressure is not less than 1 torr and not more than 20 torr.

10. The dopant diffusion method according to claim 1, wherein the semiconductor is a monocrystalline silicon.

11. A method of manufacturing a semiconductor device including a semiconductor with a dopant element diffused therein, the method comprising:
diffusing a dopant element into the semiconductor through an oxide film, the dopant element being contained in a compound gas having a gas partial pressure of not less than 0.1 torr and not more than 800 torr, and a temperature of the semiconductor being set less than 750° C. and not more than 950° C.

12. The method of manufacturing a semiconductor device according to claim 11, further including, before the diffusing, forming the oxide film on a surface of the semiconductor.

13. The method of manufacturing a semiconductor device according to claim 12, further including, before the forming the oxide film on the surface of the semiconductor, supplying a reducing gas to remove another oxide film formed on the surface of the semiconductor.

14. The method of manufacturing a semiconductor device according to claim 11, wherein the oxide film has a thickness of 1 nanometer or less.

15. The method of manufacturing a semiconductor device according to claim 12, wherein the oxide film is formed by exposing the semiconductor to a chemical solution.

16. The method of manufacturing a semiconductor device according to claim 15, wherein the chemical solution includes hydrogen peroxide.

17. The method of manufacturing a semiconductor device according to claim 11, wherein the dopant diffused into the semiconductor has a peak concentration of 3×10¹⁹ cm⁻³ or more.

18. The method of manufacturing a semiconductor device according to claim 11, wherein the dopant element is phosphorus or arsenic.

19. The method of manufacturing a semiconductor device according to claim 11, wherein the gas partial pressure is not less than 1 torr and not more than 20 torr.

20. The method of manufacturing a semiconductor device according to claim 11, wherein the semiconductor is a monocrystalline silicon.
